(19) United States
(12) Patent Application Publication
(10) Pub. No.: US 2026/0088245 A1
(43) Pub. Date: Mar. 26, 2026

(54) POSITIONER FOR ANALYTIC INSTRUMENTS WITHIN VACUUM CHAMBER

(71) Applicant: CAMECA INSTRUMENTS, INC., Madison, WI (US)

(72) Inventors: Joseph Hale Bunton, Fitchburg, WI (US); Russell Charles Manzke, Middleton, WI (US)

(73) Assignee: CAMECA INSTRUMENTS, INC., Madison, WI (US)

(21) Appl. No.: 19/108,838

(22) PCT Filed: Oct. 19, 2023
(86) PCT No.: PCT/US2023/077253

§ 371 Date: Mar. 5, 2025

Related U.S. Application Data
(60) Provisional application No. 63/418,275, filed on Oct. 21, 2022.

(51) Int. Cl. H01J 37/20; G01Q 10/04; H01J 37/244; H01J 37/26

(52) U.S. Cl. CPC H01J 37/20; G01Q 10/04; H01J 37/244; H01J 37/26; H01J 2237/20207; H01J 2237/20221

(57) ABSTRACT

A positioner for analytical instruments (e.g., atom probe microscopes or other nanoscale microscopes) includes a major carriage translatable with respect to a vacuum chamber wall, and a minor carriage connected to the major carriage by multiple spaced actuators allowing the minor carriage to translate and/or tilt with respect to the major carriage. Arms then extend from the minor carriage through the vacuum chamber wall to connect to an instrument. The instrument may be rapidly extended or retracted within the vacuum chamber via its connection to the major carriage, and may be more finely translated and/or tilted via its connection to the minor carriage. A damping arrangement isolates the instrument from vibration.

### FIELD OF THE INVENTION

This document concerns an invention relating generally to positioners for analytic instruments within vacuum chambers, and more specifically to positioners allowing analytic instruments to be properly situated within vacuum chambers with respect to specimens to be analyzed.

### BACKGROUND OF THE INVENTION

Many analytic instruments that provide nanoscale analysis of material specimens, such as transmission electron microscopes (TEM), scanning transmission electron microscopes (STEM), atomic force microscopes (AFM), scanning tunneling microscopes (STM), and atom probe microscopes (APM) require high-vacuum conditions for operation. It is useful to have arrangements that combine these instruments such that different types of analyses can be performed on a specimen without the need to move the specimen from instrument to instrument, particularly since preparations for analyses (e.g., the need to pump the chamber to high-or ultra-high vacuum conditions) can be time-consuming. However, these instruments can be bulky, as well as sensitive to the presence of other instruments, making it difficult to accommodate two or more instruments within a vacuum chamber (which is typically small, as larger chambers tend to incur greater preparation time and other operational difficulties). As an example, APMs need to be positioned extremely close to the specimens being analyzed, and their presence tends to disturb measurements from other instruments owing to their electromagnetic fields and radiant heat dissipation. This issue can require that the APM and other instruments be interchanged with each other, with each moving toward the specimen when it is their turn to obtain measurements, and each moving away from the specimen when measurements are complete. This is difficult to accomplish without enlarging the size of the vacuum chamber, leading to the aforementioned difficulties. Additionally, movement of an instrument is itself a challenge, as most instruments require very precise positioning versus a specimen, and it is difficult to devise extension/retraction arrangements that accurately reposition an instrument in its original position after being retracted and reextended.

Because much of the discussion below will focus on the use of APMs as an exemplary analytic instrument, following is a brief review of the structure and operation of typical APMs. A typical APM includes a specimen mount and an ion detector. During typical analysis, a specimen is situated in the specimen mount and a positive electrical charge (e.g., a baseline voltage) is applied to the specimen such that the electrostatic field near the apex of the specimen (the surface closest to, and facing, the detector) is approximately 90% of that required to spontaneously ionize surface atoms (generally on the order of 5 to 50 volts per nanometer). The detector is spaced from the apex (tip) of the specimen and is either grounded or negatively charged. A local electrode may be located between the specimen and the detector, having an aperture aligned between the specimen and the detector, and the local electrode may be either grounded or negatively charged. (The local electrode is sometimes referred to as an “extraction electrode”; additionally, because electrodes in an APM typically serve as electrostatic lenses, the term “lens” is sometimes used in place of the term “electrode.”) An energy beam pulse (e.g., a laser beam pulse, electron beam pulse, ion beam pulse, etc.), positive electrical pulse (above the baseline voltage), and/or other energy pulse (e.g., RF pulse) is intermittently applied to the specimen to increase the probability that surface atoms on the specimen will ionize. Alternatively or additionally, a negative voltage pulse can be applied to any local electrode in synchrony with the foregoing energy pulse(s).

Occasionally, a pulse will cause ionization of a single atom near the apex of the specimen. The ionized atom(s) separate or “evaporate” from the specimen's surface, pass through the aperture in the local electrode (if present), and impact the surface of the detector, typically a microchannel plate (MCP). The elemental identity of an ionized atom can be determined by measuring its time of flight (TOF), the time between the pulse that liberates the ion from the surface of the specimen and the time it impinges on the detector. The velocity of the ions (and thus their TOF) varies based on the mass-to-charge-state ratio (m/n) of the ionized atom, with lighter and/or more highly charged ions taking less time to reach the detector. Since the TOF of an ion is indicative of the mass-to-charge ratio of the ion, which is in turn indicative of elemental identity, the TOF can help identify the composition of the ionized atom. In addition, the APM acts as a “point projection microscope” whereby the location of the ionized atom on the surface of the specimen corresponds to the location of the atom's impact on the detector, thereby allowing determination of the ionized atom's original location on the specimen. Thus, as the specimen is evaporated, a three-dimensional map or image of the specimen's constituent atoms can be constructed. While the image represented by the map is a point projection, with atomic resolution and a magnification of over 1 million times, the map / image data can be analyzed in virtually any orientation, and thus the image can be considered more tomographic in nature. Further details on APMs can be found, for example, in U.S. Pat. Nos. 5,440,124; 7,157,702; 7,652,269; 7,683,318; 7,884,323; 8,074,292; 8,153,968; 8,276,210; 8,513,597; 8,575,544; 8,670,608; and 10,614,995, as well as in the patents and other literature referenced in the foregoing documents.

### SUMMARY OF THE INVENTION

The invention, which is defined by the claims set forth at the end of this document, is directed to an instrument positioner which at least partially alleviates the aforementioned problems with instrument positioning and/or exchange. A basic understanding of some of the features of preferred versions of the invention can be attained from a review of the following brief summary of the invention, with more details being provided elsewhere in this document. To assist in the reader's understanding, the following review makes reference to the accompanying drawings (which are briefly reviewed in the “Brief Description of the Drawings” section following this Summary section of this document).

FIGS. 1-5 illustrate an exemplary version of the instrument positioner as it might appear when used to position an exemplary atom probe microscope (APM) within a vacuum chamber. The vacuum chamber is largely removed from the drawings for sake of clarity, but can be envisioned in FIG. 1 as being attached to a port 52 in a vacuum subchamber 50, with the vacuum chamber's walls being generally situated within the boundary depicted by phantom (dashed) line 10. The APM 100, more specifically its ion optics (local electrode 102, decelerating lens 104, and decelerating lens 106), are seen protruding through the vacuum subchamber port 52 (and thus into the vacuum chamber 10), with the positioner 200 for the APM 100 resting behind a rear wall 54 of the vacuum subchamber 50. The positioner 200 can extend the APM 100 through the port 52 (and thus further into the vacuum chamber 10 for analysis of a specimen therein), or retract the APM 100 through the port 52 (and thus further into the vacuum subchamber 50 to be stowed therein as other instruments analyze the specimen). FIGS. 2-4 then show the APM 100 and positioner 200 without the vacuum subchamber 50.

The exemplary positioner 200 includes a major carriage 202 which is displaceable with respect to the port 52 (and thus the vacuum chamber wall 10) via a major actuator 204 thereon, e.g., a pneumatic cylinder. As best seen in FIGS. 3-4, the major actuator 204 has a shaft 206 extending along an instrument axis (an axis directed through the instrument and toward the specimen mount within the vacuum chamber 10) to affix to the vacuum subchamber rear wall 54. A minor carriage 208 is then displaceable with respect to the major carriage 202 via four minor actuators 210 thereon, e.g., servomotors, here situated near the four corners of the (square) minor carriage 208. The minor actuators 210 have shafts 212 which extend to affix to the major carriage 202. Four elongated instrument support arms 214 then extend from the minor carriage 208 and through the major carriage 202, which has one or more openings (not shown) through which the instrument support arms 214 freely extend without interference. The instrument support arms 214 then extend through the subchamber rear wall 54, with tight gaskets (not shown) or similar measures allowing the instrument support arms 214 to displace along their lengths through the rear wall 54 without losing any (or any substantial) vacuum within the vacuum subchamber 50.

The APM 100 (or other instrument) is then affixed to instrument support arm ends 216 within the vacuum subchamber 50. Thus, displacement of the major carriage 202 with respect to the vacuum chamber wall 10 translates the minor carriage 208, thereby translating any instrument affixed to the instrument support arms 214 within the vacuum chamber. The major actuator 204 driving the major carriage 202 preferably has a stroke/displacement sufficient to move the instrument to a specimen analysis position within the vacuum chamber 10, and to retract the instrument from the vacuum chamber 10 such that the instrument does not interfere with analyses from other instruments. Additionally, displacement of the minor actuators 210 by equal lengths translates the minor carriage 208 with respect to the major carriage 202, thereby translating any instrument affixed to the instrument support arms 214. However, unequal displacement of the minor actuators 210 tilts the minor carriage 208 with respect to the major carriage 202, thereby tilting any instrument affixed to the instrument support arms 214. When the positioner 200 is used with an APM 100, the instrument support arms 214 need not be pivotally mounted to the minor carriage 208 and/or to the instrument, as the unequal displacement of the minor actuators 210 is sufficient to tilt the instrument up to approximately one degree (which is typically sufficient for an APM 100). Thus, the major actuator 204 and major carriage 202 provide bulk positioning of the instrument between analysis and stowed positions, while the minor actuators 210 and minor carriage 208 provide fine positioning of the instrument into its analysis position. The positioner 200 beneficially provides highly repeatable positioning of the instrument, e.g., it can be rapidly withdrawn from its analysis position to its stowed position, and then extended back to its analysis position with little or no difference between the earlier and later analysis positions.

In the foregoing arrangement, the minor actuators 210 are preferably each equidistantly spaced from the instrument axis, and arrayed about an actuator path extending about the instrument axis, with each minor actuator 210 being equally spaced from its adjacent minor actuators 210 along the actuator path. Similarly, the instrument support arms 214 are preferably each equidistantly spaced from the instrument axis, and arrayed about an arm path extending about the instrument axis, with each minor actuator 210 being equally spaced from its adjacent instrument support arms 214 along the arm path. This arrangement provides for greater predictability in the motion of the instrument support arms 214, and thereby eases control of the positioning of the instrument. Additionally, the circumference of the actuator path is preferably greater than the circumference of the arm path, as this provides the minor actuators 210 with greater leverage and provides greater instrument tilt with less effort from the minor actuators 210.

The APM 100 shown in the drawings provides a particularly compact design while still providing acceptable ion mass resolution and location measurements. A local electrode 102 is situated at the end of the APM 100 closest to the specimen, followed by a decelerating lens 104 (electrode) which tends to slow and spread specimen ions extracted by the local electrode 102, in turn followed by an elongated conical accelerating electrode 106 which tends to collimate the specimen ions onto an ion detector 108. The detector 108 is situated within the vacuum subchamber 50, which effectively serves as an extended portion of the vacuum chamber 10. The vacuum subchamber 50 can beneficially be pumped to higher vacuum than that in the vacuum chamber 10, which can help to increase the performance of the detector 108.

The positioner 200 also preferably includes dampers 250, shown in FIGS. 4a and 4b, which help isolate the APM 100 (or other instrument) from vibration when moving to and from to its analysis position. In FIGS. 4a and 4b, the dampers 250 are shown mounted on the wall of, and extending into, the vacuum subchamber 50. Each damper 250 includes a conduit 252 which extends from the outer circumference of the vacuum subchamber 50 to a collapsible bellows 254, with the bellows 254 opening onto a cylinder 256 containing a piston 258 sandwiched between viscoelastic members 260. An elongated damping member 262 then extends from a damping member pivot end 264 at the piston 258 and through the bellows 254 and the conduit 252 to protrude into the vacuum subchamber 50, where it terminates in a damping member instrument end 266. When the vacuum subchamber 50 is at (or approaching) ambient pressure, the bellows 254 expand and the damping member instrument end 266 is spaced from, but directed toward, the instrument. However, when the vacuum subchamber 50 is evacuated, ambient pressure compresses the bellows 254 and pushes the damping member 262 into the vacuum subchamber 50 until its damping member instrument end 266 engages the instrument (here within a socket 110 defined adjacent the detector 108, FIG. 2). Because the bellows 254 and viscoelastic members 260 of each damper 250 resiliently press the damping member 262 against the instrument, and allow pivoting of the damping member 262 as the instrument is displaced into and out of the vacuum chamber 10 (more particularly the vacuum subchamber 50), each damper 250 allows the instrument to move between stowed and analysis positions while damping external vibration that might be transmitted to the instrument. By situating opposing dampers 250 about the instrument (as seen particularly in FIG. 4b), their forces are offset such that neither damper deflects the instrument's travel off of the instrument axis.

The invention is not limited to the exemplary positioner, and can be provided in different forms. More broadly, the invention encompasses a positioner having three or more elongated instrument support arms wherein each instrument support arm extends through a wall of the vacuum chamber to an instrument support arm end within the vacuum chamber, and which is configured to translate along its length within the vacuum chamber wall. Equal translation of the instrument support arms with respect to the vacuum chamber wall translates any instrument affixed to the instrument support arm ends within the vacuum chamber, and unequal translation of the instrument support arms with respect to the vacuum chamber wall tilts any instrument affixed to the instrument support arm ends within the vacuum chamber.

The invention also encompasses a positioner having a minor carriage configured to displace with respect to a wall of the vacuum chamber, and elongated instrument support arms which are rigidly affixed to the minor carriage and displaceable along their lengths within the vacuum chamber wall, and which have an instrument affixed thereto within the vacuum chamber. Equal displacement of the instrument support arms with respect to the vacuum chamber wall displaces any instrument affixed to the instrument support arm ends within the vacuum chamber, whereas unequal displacement of the instrument support arms with respect to the vacuum chamber wall tilts any instrument affixed to the instrument support arm ends within the vacuum chamber.

The invention further encompasses a positioner having a major carriage displaceable with respect to a vacuum chamber wall; a minor carriage having instrument support arms extending therefrom and through the vacuum chamber wall; and minor actuators wherein each minor actuator displaces the minor carriage with respect to the major carriage. Displacement of the major carriage with respect to the vacuum chamber wall displaces the minor carriage, thereby displacing any instrument affixed to the instrument support arms within the vacuum chamber. Additionally, equal displacement of the minor actuators displaces the minor carriage with respect to the major carriage, thereby displacing any instrument affixed to the instrument support arms within the vacuum chamber, whereas unequal displacement of the minor actuators tilt the minor carriage with respect to the major carriage, thereby tilting any instrument affixed to the instrument support arms within the vacuum chamber.

Any one or more of the following features may also be present in any of the versions of the invention described above:
(1) The positioner can include a minor carriage wherein each instrument support arm extends from the minor carriage, and wherein the minor carriage has three or more minor actuators, with each minor actuator being configured to translate the minor carriage with respect to the vacuum chamber wall. Equal translation of the minor actuators translates the minor carriage and the instrument support arms extending therefrom with respect to the vacuum chamber wall, thereby translating any instrument affixed to the instrument support arm ends within the vacuum chamber, and unequal translation of the minor actuators tilts the minor carriage with respect to the vacuum chamber, thereby unequally translating the instrument support arms extending therefrom and tilting any instrument affixed to the instrument support arm ends within the vacuum chamber.
(2) The positioner can include a major carriage translatable with respect to the vacuum chamber wall, wherein each minor actuator extends between the major carriage and the minor carriage. Translation of the major carriage with respect to the vacuum chamber wall translates the minor carriage and the instrument support arms extending therefrom, thereby translating any instrument affixed to the instrument support arm ends within the vacuum chamber.
(3) The positioner can include a major actuator configured to translate or otherwise displace the minor carriage with respect to the major carriage, e.g., a pneumatic cylinder. The major actuator preferably has a greater range of travel than the minor actuators.
(4) The instrument support arms can be rigidly affixed to an analytic device (preferably within the vacuum chamber), and/or to the minor carriage.
(5) The instrument support arms can extend from the minor carriage through the major carriage.
(6) The minor actuators may each be equidistantly spaced from an instrument axis extending through the minor carriage and the vacuum chamber wall, and may be arrayed about an actuator path extending about the instrument axis, with each minor actuator being equally spaced from its adjacent minor actuators along the actuator path.
(7) The instrument support arms may each be equidistantly spaced from the instrument axis, and arrayed about an arm path extending about the instrument axis, with each minor actuator being equally spaced from its adjacent instrument support arms along the arm path. The circumference of the actuator path may be greater than the circumference of the arm path.
(8) The positioner may be used for positioning of an APM, A preferred APM includes an elongated conical electrode, preferably an ion-accelerating electrode, spaced from the instrument support arm by an ion detector. This arrangement may further include a local electrode and an ion-decelerating electrode, with the ion-decelerating electrode being situated between the local electrode and the conical electrode.
(9) Where the positioner is used for positioning of an instrument (e.g., an APM) which includes an ion detector, the positioner and/or the instrument may include a vacuum subchamber within the vacuum chamber, wherein the vacuum subchamber is configured to provide higher vacuum than the vacuum chamber.
(10) The positioner may include damping members which each extend between a pivot end flexibly mounted with respect to the vacuum chamber wall, and an instrument end adjacent the instrument. These damping members may be configured such that vacuum within the vacuum chamber urges the damping members to engage the damping member instrument ends with the instrument. The damping member instrument ends may detachably engage the instrument, e.g. by fitting within sockets in the instrument.

Further potential advantages, features, and objectives of the invention will be apparent from the remainder of this document in conjunction with the associated drawings.

### BRIEF DESCRIPTION OF THE DRAWINGS

FIG. 1 depicts an exemplary analytic instrument positioner 200 as used to position an atom probe microscope (APM) 100 within a vacuum chamber 10, with the APM's lenses 102, 104, and 106 shown protruding from a vacuum subchamber port 52, and with the APM's ion detector (not shown) being within a vacuum subchamber 50.

FIG. 2 illustrates the arrangement of FIG. 1 with the vacuum subchamber 50 removed, thereby showing the APM's ion optics (local electrode 102, decelerating lens 104, and decelerating lens 106) with its ion detector 50.

FIGS. 3a and 3b illustrate side views of the arrangement of FIG. 2, with FIG. 3a showing the APM 100 in an at least partially retracted position and FIG. 3b showing the APM 100 in an at least partially extended position.

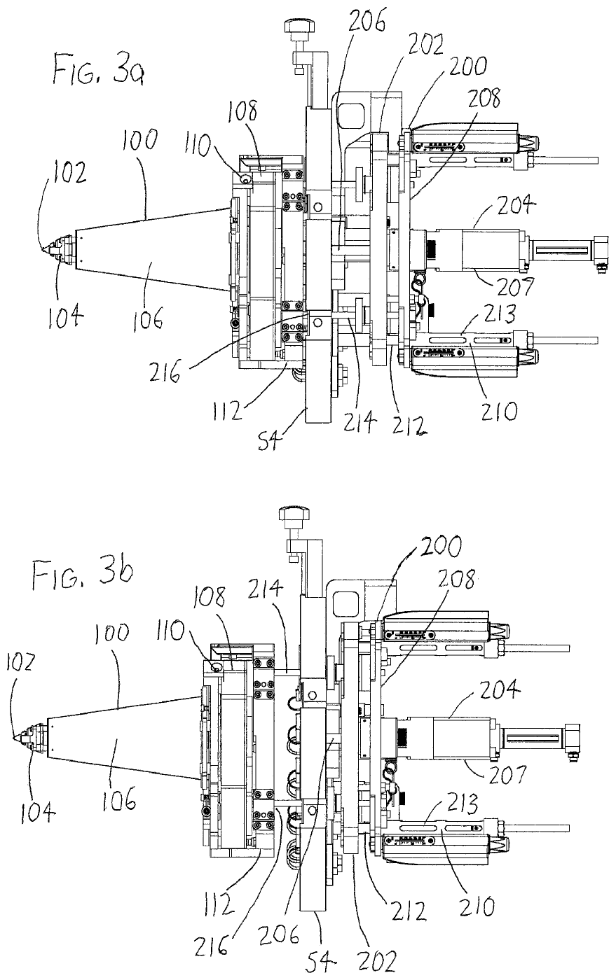

FIG. 4a is a top view of the arrangement of FIG. 1, and FIG. 4b is a sectional view along line A-A of FIG. 4a, illustrating an exemplary damper 250 used to stabilize the APM 100 during extension and retraction.

### DETAILED DESCRIPTION OF EXEMPLARY VERSIONS OF THE INVENTION

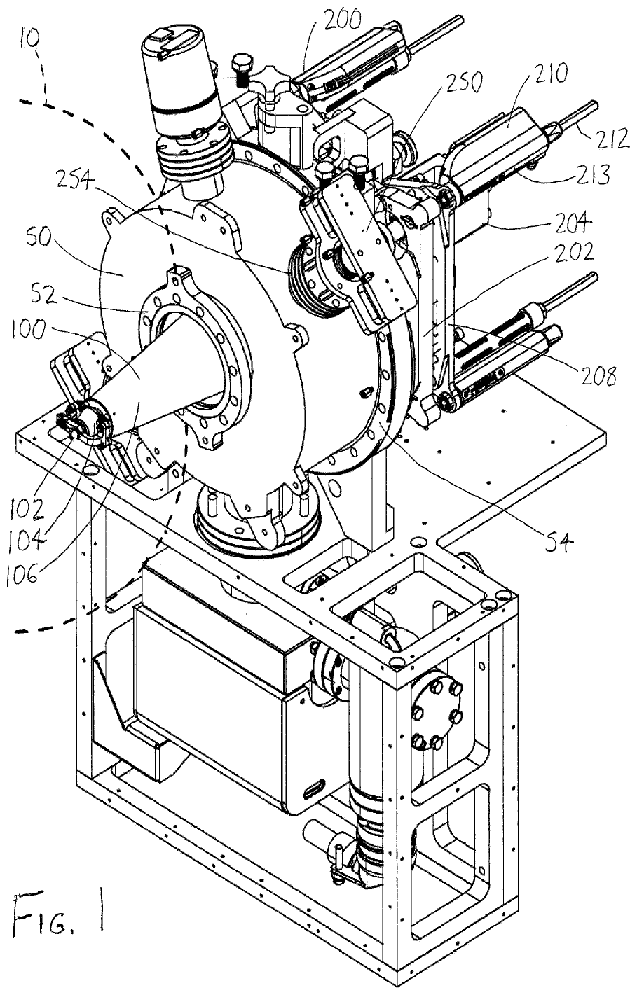

FIG. 1 depicts an exemplary version of the positioner 200 as it might be presented when used to position an atom probe microscope (APM) 100 within a vacuum chamber. In FIG. 1, only the APM's ion optics (its local electrode 102, decelerating lens 104, and decelerating lens 106) are visible, with the remainder of the APM 100 (primarily its detector) being situated within a vacuum subchamber 50, in an arrangement such as that described in U.S. Pat. No. 10,614,995. The vacuum subchamber 50 has an port 52 configured to mount on a vacuum chamber 10 of another instrument, e.g., a transmission electron microscope (TEM), such that the vacuum subchamber 50 effectively defines a subportion of the vacuum chamber 10, with the APM's local electrode 102, decelerating lens 104, and decelerating lens 106 shown protruding from the vacuum subchamber 50 into the vacuum chamber. Within the vacuum subchamber 50, the APM 100 is affixed to the positioner 200, in particular, to the ends of the instrument support arms 214 extending through the rear wall 54 of the vacuum subchamber 50. The APM 100 can thus be moved by the positioner 200 within the vacuum subchamber 50 (and within the vacuum chamber 10) such that its local electrode 102 can be situated immediately adjacent a specimen undergoing TEM analysis within the vacuum chamber 10.

Since the presence of the APM 100 can interfere with TEM imaging of the specimen, the major actuator 204 is provided to rapidly move the APM 100 away from (and thereafter toward) the specimen. The major actuator 204 (e.g., a pneumatic cylinder) has its travel axis aligned with the instrument axis, i.e., the axis of the ion flight cone when the APM 100 is in its default position. The major actuator 204 has one actuating portion (e.g., its body/cylinder 207) affixed to the major carriage 202 (shown shaped roughly as a square plate), and its other actuating portion (e.g., the shaft/piston 206 that translates within the body/cylinder 207) affixed to the vacuum subchamber rear wall 54. Operation of the major actuator 204 therefore translates the major carriage 202 toward or away from the vacuum subchamber rear wall 54, and thus toward or away from the vacuum subchamber 50 and TEM vacuum chamber 10.

In similar fashion, each minor actuator 210 has one actuating portion (e.g., its body/cylinder 213) affixed to the major carriage 202, and its other actuating portion (e.g., its shaft/piston 212) linked to the minor carriage 208. Actuation of two adjacent minor actuators 210 will tilt the minor carriage 208 about a horizontal or vertical axis on the minor carriage 208, whereas actuation of two nonadjacent minor actuators 210, or all three minor actuators 210, by different respective distances will tilt the minor carriage 208 about both the horizontal and vertical axes. Actuation of the minor actuators 210 by the same amounts will translate the minor carriage 208 along the instrument axis. The minor carriage 208 bears instrument support arms 214 situated at opposite sides of the tilt axes of the minor carriage 208—e.g., near the corners of the minor carriage 208—which extend through one or more apertures (not shown) in the vacuum subchamber rear wall 54 to the APM 100 (more specifically, to an APM mount 112 adjacent the APM's detector). Tilting of the minor carriage 208 therefore extends or retracts selected instrument support arms 214 into or out of the vacuum subchamber rear wall 54, thereby tilting the APM 100 such that its local electrode 102 (and ion flight cone) can be deflected from the instrument axis. Because the airtight fitting of the instrument support arms 214 within the vacuum subchamber rear wall 54 only allows limited tilting of the APM 100, this deflection is small (but sufficient), with the ion flight cone axis tilting by no more than one degree or so from the instrument axis.

The major actuator 204 can therefore rapidly translate the APM 100 over greater distances toward or away from the specimen (and the TEM within the vacuum chamber 10): its actuation moves the major carriage 202 toward or away from the vacuum subchamber rear wall 54, thereby also carrying the minor carriage 208 (which is linked to the major carriage 202 by the minor actuator 210) and the APM 100 (which is linked to the minor carriage 208 by the instrument support arms 214). The minor actuator 210 can perform fine positioning by adjusting the minor carriage 208 to translate and/or tilt the APM 100 with respect to the instrument axis. Preferably, in practice, after the APM 100 is positioned near the specimen via the major actuator 204, the APM's local electrode 102 is focused on the specimen by use of the minor actuator 210 such that APM measurements can be obtained. However, the major actuator 204 allows the APM 100 to be quickly retracted from the specimen when TEM measurements are to be acquired, and thereafter extended toward the specimen when TEM measurements are completed, with the local electrode 102 being situated at or very near its original measurement position. This is of significant value, as alignment of the local electrode 102 with a region of interest on an APM specimen can be a time-consuming process.

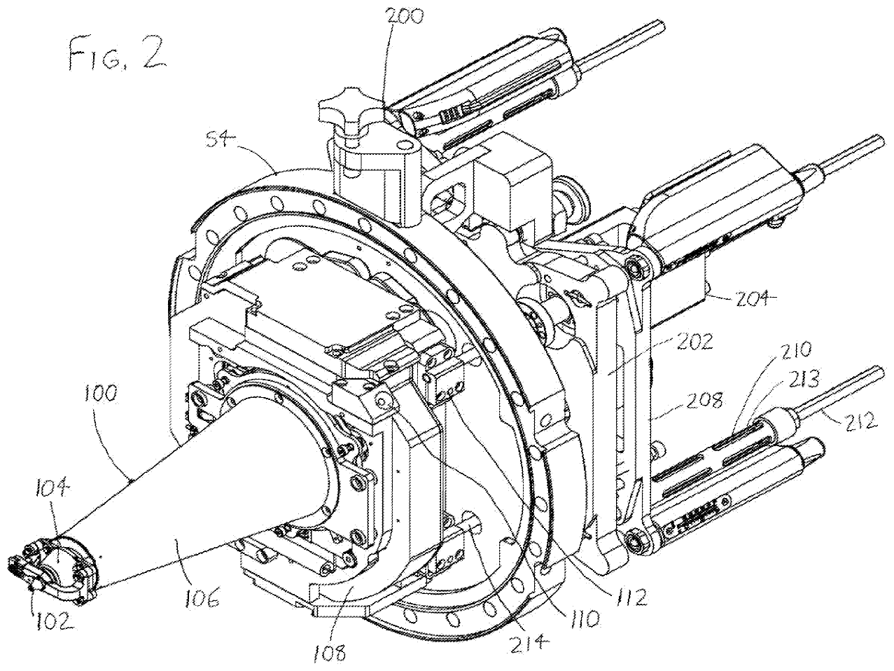

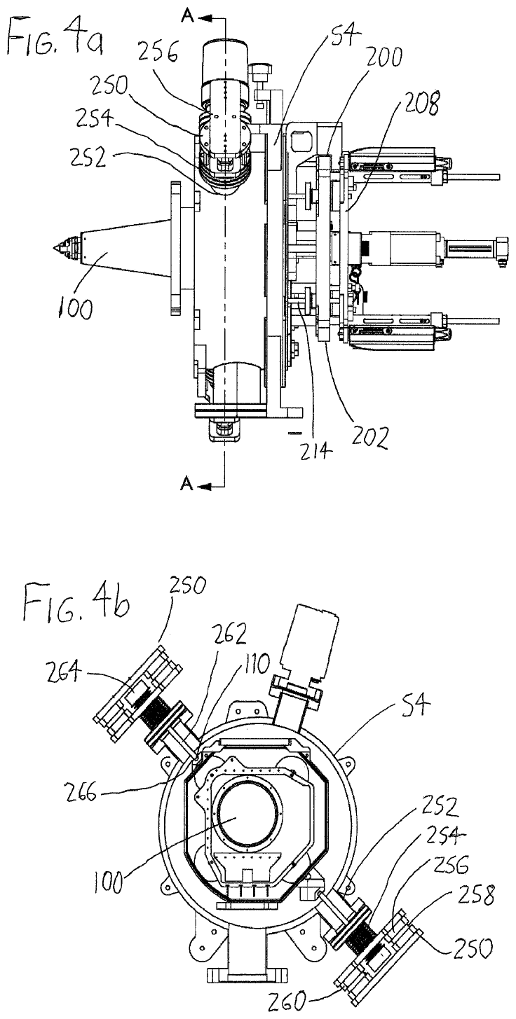

The foregoing arrangement is enhanced by a damping system that helps reduce or eliminate vibration in the APM 100. Since the APM 100 is supported in a cantilever arrangement (via the instrument support arms 214 extending from the vacuum subchamber rear wall 54), it can be susceptible to vibration from the environment (e.g., transmitted from the floor or other surroundings, or from audible noise), and/or from extension/retraction, and such vibration can interfere with TEM or other analyses. As seen in FIG. 1, dampers 250 are provided on the vacuum subchamber 50, with FIGS. 4a-4b providing further details. Each damper 250 includes a damping member 262 having a damping member instrument end 266 receivable in a concave damping receptacle (socket) 110 in the APM mount 112 (seen in FIGS. 2 and 4b), and an opposing damping member pivot end 264 bearing a thin piston 258 which is sandwiched (or otherwise cushioned) within a cylinder 256 by viscoelastic members 260 (e.g., sorbathane disks). A vacuum-tight bellows 254 connects the cylinder 256 to the vacuum subchamber 50. When the vacuum subchamber 50 is evacuated, atmospheric pressure compresses the bellows 254, pushing the damping member 262 into the vacuum subchamber 50 until the damping member instrument end 266 engages the damping receptacle 110 in the detector housing. As the linear actuators translate and/or tilt the APM 100 and its detector, the flexible bellows 254 allows the first end of the damper 250 connecting rod to follow (and urge against) the APM mount 112. The viscoelastic members 260, and to some extent the bellows 254, then usefully damp vibration of the APM 100, with the dampers 250 on the opposite sides of the APM 100 resisting displacement of the APM 100 from the instrument axis as it translates within the subchamber 50. At the same time, the dampers 250 maintain the vacuum of the vacuum subchamber 50 and chamber 10, and generate little or no heat that might potentially disrupt TEM or APM analyses.

As the APM 100 (or at least the bulk of it) is ideally spaced as far as possible from the specimen when retracted so as not to interfere with TEM measurements, the ion optics of the exemplary APM 100 are of interest because they elongate the length of the ion flight path between the local electrode 102 and the detector 108, thereby spacing the detector 108 further from the specimen (and increasing time of flight, and thus the APM's mass resolution). This is done by following the local electrode 102 with an ion-decelerating electrostatic lens which tends to increase the spread of ions emitted from the specimen, followed by an ion-accelerating electrode which collimates the spread ions onto the detector 108. Thus, for example, ions from a positively-charged specimen could accelerate toward the local electrode 102 at ground potential, then be decelerated through an aperture in the negatively-charged electrostatic lens 104, and then accelerated onto the detector by a positively-charged conical accelerating electrode 106.

It should be understood that the versions of the invention described above are merely exemplary, and the invention is not intended to be limited to these versions. As an example, the translation and tilt of the minor carriage 208 could be achieved with as few as three instrument support arms 214, or with more than four instrument support arms 214. However, the symmetrical arrangement provided by the illustrated four instrument support arms 214 tends to provide easier control. As another example, the minor carriage 208 could achieve greater tilt if the instrument support arms 214 were pivotally mounted to the minor carriage 208 and the instrument (or at least one of these), but greater tilt is not needed where the instrument is an APM, and pivotal connections (e.g., by ball-and-socket universal joints) tend to introduce positioning uncertainties. As a final example, while the described arrangement uses a pneumatic cylinder as the major actuator 204 and DC servomotors as the minor actuators 210, different actuators could be used instead. The described arrangement beneficially allows the minor (servomotor) linear actuators 210 to be depowered once fine positioning is completed, thereby avoiding further heat input that could disturb TEM or other analyses. The pneumatic major actuator 204 can thereafter be activated and deactivated as desired for extension and retraction of the APM 100 with negligible heat input into the vacuum chamber.

The scope of rights to the invention is limited only by the claims set out below, and the invention encompasses all different versions that fall literally or equivalently within the scope of these claims. In these claims, no element therein should be interpreted as a “means-plus-function” element or a “step-plus-function” element pursuant to 35 U.S.C. § 112(f) unless the words “means for”or “step for”are explicitly used in the particular element in question.

1. A positioner for an analytical instrument within a vacuum chamber, the positioner including three or more elongated instrument support arms wherein each instrument support arm:
a. extends through a wall of the vacuum chamber wall to an instrument support arm end within the vacuum chamber,
b. is configured to translate along its length within the vacuum chamber wall,
whereby:
A. equal translation of the instrument support arms with respect to the vacuum chamber wall translates any instrument affixed to the instrument support arm ends within the vacuum chamber,
B. unequal translation of the instrument support arms with respect to the vacuum chamber wall tilts any instrument affixed to the instrument support arm ends within the vacuum chamber.

2. The positioner of claim 1 further including a minor carriage:
a. wherein each instrument support arm extends from the minor carriage,
b. having three or more minor actuators, each minor actuator being configured to translate the minor carriage with respect to the vacuum chamber wall,
whereby:
A. equal translation of the minor actuators translates the minor carriage and the instrument support arms extending therefrom with respect to the vacuum chamber wall, thereby translating any instrument affixed to the instrument support arm ends within the vacuum chamber,
B. unequal translation of the minor actuators tilts the minor carriage with respect to the vacuum chamber, thereby unequally translating the instrument support arms extending therefrom and tilting any instrument affixed to the instrument support arm ends within the vacuum chamber.

3. The positioner of claim 1 wherein the instrument support arms are rigidly affixed to the minor carriage.

4. The positioner of claim 2:
a. further including a major carriage translatable with respect to the vacuum chamber wall,
b. wherein each minor actuator extends between the major carriage and the minor carriage, each minor actuator being configured to displace the minor carriage with respect to the major carriage,
whereby translation of the major carriage with respect to the vacuum chamber wall translates the minor carriage and the instrument support arms extending therefrom, thereby translating any instrument affixed to the instrument support arm ends within the vacuum chamber.

5. The positioner of claim 4 wherein the instrument support arms extend from the minor carriage through the major carriage.

6. The positioner of claim 2 wherein:
a. the minor actuators are:
(1) each equidistantly spaced from an instrument axis extending through the minor carriage and the vacuum chamber wall, and
(2) arrayed about an actuator path extending about the instrument axis, with each minor actuator being equally spaced from its adjacent minor actuators along the actuator path,
b. the instrument support arms are:
(1) each equidistantly spaced from the instrument axis, and
(2) arrayed about an arm path extending about the instrument axis, with each minor actuator being equally spaced from its adjacent instrument support arms along the arm path.

7. The positioner of claim 6 wherein the circumference of the actuator path is greater than the circumference of the arm path.

8. The positioner of claim 1 further including an instrument rigidly affixed to the instrument support arm ends within the vacuum chamber.

9. The positioner of claim 8 wherein the instrument includes an atom probe ion detector.

10. The positioner of claim 9 wherein:
a. the instrument includes an elongated conical electrode, and
b. the ion detector is situated between the conical electrode and the instrument support arm ends.

11. The positioner of claim 9 wherein:
a. the instrument includes an electrode array having:
(1) a local electrode,
(2) an ion-accelerating electrode, and
(3) an ion-decelerating electrostatic lens between the local electrode and the ion-accelerating electrode, and
b. the ion detector is situated between the electrode array and the instrument support arm ends.

12. The positioner of claim 9 wherein:
a. the instrument includes a vacuum subchamber configured to provide higher vacuum than the vacuum chamber, and
b. the ion detector is situated within the vacuum subchamber.

13. The positioner of claim 1 further including:
a. an instrument affixed to the instrument support arm ends within the vacuum chamber,
b. damping members wherein each damping member extends between:
(1) a damping member pivot end flexibly mounted with respect to the vacuum chamber wall, and
(2) a damping member instrument end adjacent the instrument, wherein vacuum within the vacuum chamber extends the damping members to engage the damping member instrument ends with the instrument.

14. The positioner of claim 1 further including:
a. an instrument affixed to the instrument support arm ends within the vacuum chamber,
b. damping members wherein each damping member extends between:
(1) a damping member pivot end flexibly mounted with respect to the vacuum chamber wall, and
(2) a damping member instrument end adjacent the instrument, wherein vacuum within the vacuum chamber extends the damping members to engage the damping member instrument ends with the instrument.

15. The positioner of claim 1 further including:
a. an instrument affixed to the instrument support arm ends within the vacuum chamber,
b. damping members wherein each damping member extends between:
(1) a damping member pivot end flexibly mounted with respect to the vacuum chamber wall, and
(2) a damping member instrument end fit within a socket in the instrument.

16. The positioner of claim 1 further including:
a. an instrument affixed to the instrument support arm ends within the vacuum chamber,
b. damping members wherein each damping member extends between:
(1) a damping member pivot end mounted on an inflatable member affixed with respect to the vacuum chamber wall, and
(2) a damping member instrument end configured to engage the instrument.

17. A positioner for an analytical instrument within a vacuum chamber, the positioner including:
a. a minor carriage configured to displace with respect to a wall of the vacuum chamber,
b. elongated instrument support arms:
(1) rigidly affixed to the minor carriage,
(2) being translatable along their lengths within the vacuum chamber wall, and
(3) having an instrument affixed thereto within the vacuum chamber,
whereby:
A. equal translation of the instrument support arms with respect to the vacuum chamber wall translates any instrument affixed to the instrument support arm ends within the vacuum chamber,
B. unequal translation of the instrument support arms with respect to the vacuum chamber wall tilts any instrument affixed to the instrument support arm ends within the vacuum chamber.

18. The positioner of claim 17 further including:
a. a major carriage,
b. a major actuator configured to displace the major carriage with respect to a wall of the vacuum chamber,
c. minor actuators affixed between the major carriage and the minor carriage,
d. major actuator configured to displace the minor carriage with respect to the major carriage.

19. A positioner for an analytical instrument within a vacuum chamber, the positioner including:
a. a major carriage displaceable with respect to a vacuum chamber wall,
b. a minor carriage having instrument support arms extending therefrom and through the vacuum chamber wall,
c. minor actuators, each minor actuator displacing the minor carriage with respect to the major carriage,
whereby:
A. displacement of the major carriage with respect to the vacuum chamber wall displaces the minor carriage, thereby displacing any instrument affixed to the instrument support arms within the vacuum chamber,
B. equal displacement of the minor actuators displaces the minor carriage with respect to the major carriage, thereby displacing any instrument affixed to the instrument support arms within the vacuum chamber,
C. unequal displacement of the minor actuators tilt the minor carriage with respect to the major carriage, thereby tilting any instrument affixed to the instrument support arms within the vacuum chamber.
